(19) United States
(12) Patent Application Publication
(10) Pub. No.: US 2026/0157157 A1
(43) Pub. Date: Jun. 4, 2026

(54) METHOD FOR ANNEALING HIGH-K MATERIALS

(71) Applicant: ASM IP Holding B.V., Almere (NL)

(72) Inventors: Paul Ma, Scottsdale, AZ (US); Mihaela Balseanu, Scottsdale, AZ (US); Rajkumar Jakkaraju, Phoenix, AZ (US)

(21) Appl. No.: 19/404,113

(22) Filed: Dec. 1, 2025

Related U.S. Application Data
(60) Provisional application No. 63/727,968, filed on Dec. 4, 2024.

(51) Int. Cl. H10P 95/90; H10P 34/00

(52) U.S. Cl. CPC H10P 95/90; H10P 34/10

(57) ABSTRACT

A method for annealing a material includes providing a substrate with a metal-containing material in proximity to or in contact with the material on a surface of the substrate, and exposing the metal-containing material to hydrogen radicals, where the thermal energy from the recombination of the hydrogen radicals locally heats the metal-containing material and thereby transfers the thermal energy to the material, thereby locally annealing the material.

### CROSS-REFERENCE TO RELATED APPLICATIONS

This application is a nonprovisional of, and claims priority to and the benefit of, U.S. Provisional Ser. No. 63/727,968 , filed Dec. 4, 2024 and entitled “METHOD FOR ANNEALING HIGH-K MATERIALS,” which is hereby incorporated by reference herein.

### FIELD

Examples are described that relate to methods and apparatus for annealing. More particularly, examples of the disclosure relate to a method of annealing a high-k material.

### BACKGROUND

In semiconductor device fabrication, the devices that make up an integrated circuit, such as transistors, capacitors, resistors, or the like, are generally formed in front end of line (FEOL) processes. Subsequently, interconnects to connect the devices are generally formed in back end of line (BEOL) processes. Devices and structures formed in FEOL and/or BEOL processes may be sensitive to the temperature of the respective processes. For example, excessive temperatures in FEOL and/or BEOL processes may damage or cause undesirable properties in semiconductor devices formed using FEOL and/or BEOL processes. Therefore, there exists a desire for FEOL and/or BEOL processes to be within a thermal budget and not have excessive temperatures.

FEOL and/or BEOL process can include deposition of high-k materials, which may not have a desirable crystallinity as deposited. These layers are often annealed at high temperatures to change their crystallinity. Conventional annealing process often occur at high temperatures that may damage underlying devices or components thereof. Therefore, there exists a desire to anneal high-k material layers at lower temperatures with a lower thermal budget.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. Various concepts are described in further detail in the detailed description of example embodiments of the disclosure below. This summary is not intended to necessarily identify key features or essential features of the claimed subject matter, nor is it intended to be used to limit the scope of the claimed subject matter.

Embodiments described herein provide methods for annealing a material, as well as substrate processing apparatuses to perform the methods of annealing. Various embodiments of the methods provide for the annealing of a thin film to change the crystallinity of the thin film, by using the thermal energy from the recombination of hydrogen radicals. Additional aspects will be set forth in part in the description which follows and will be apparent from the description.

In accordance with various embodiments of the disclosure, a method for annealing is provided, including providing a substrate in a chamber, wherein the substrate includes a metal-containing material on a surface of the substrate and a high-k material in proximity to or in contact with the metal-containing material; exposing the metal-containing material to hydrogen radicals, wherein the hydrogen radicals recombine at or near the metal-containing material thereby locally heating the metal-containing material; and locally annealing the high-k material, wherein the temperature within the chamber during the method is less than 500° C.

In some embodiments, locally annealing the high-k material includes heat transfer from the metal-containing material to the high-k material.

In some embodiments, the metal-containing material is metallic.

In some embodiments, the metal-containing material consists essentially of a metal.

In some embodiments, the metal-containing material includes a metal nitride.

In some embodiments, the metal nitride includes titanium nitride.

In some embodiments, locally annealing the high-k material increases the crystallinity of the high-k material.

In some embodiments, the dielectric constant of the high-k material is greater than 12 before locally annealing.

In some embodiments, the dielectric constant of the high-k material is greater than 15 after locally annealing.

In some embodiments, the metal-containing material is a metal interconnect disposed in a gap on the surface of the substrate.

In some embodiments, where recombining the hydrogen radicals produces H₂, and the method further includes a purge of the H₂.

In some embodiments, the high-k material includes a metal oxide.

In some embodiments, the high-k material is annealed up to a thickness within 150 Angstroms of the metal-containing material.

In some embodiments, the step of exposing the metal-containing material to the hydrogen radicals includes flowing hydrogen radicals from a remote plasma source.

In some embodiments, the step of exposing the metal-containing material to the hydrogen radicals consists of flowing hydrogen radicals and a carrier gas.

In some embodiments, the metal-containing material is in contact with the high-k material.

In some embodiments, the metal-containing material is co-planar with the high-k material.

In some embodiments, the metal-containing is disposed above the high-k material.

In some embodiments, the temperature during the method is below 400° C.

In accordance with various embodiments of the disclosure, a method for annealing is provided, including providing a substrate in a chamber, wherein the substrate includes a metal-containing material on a surface of the substrate and a high-k material in contact with the metal-containing material, wherein the high-k material includes a metal oxide and the metal-containing material includes titanium nitride; exposing the metal-containing material to hydrogen radicals, wherein the hydrogen radicals recombine at or near the metal-containing material thereby locally heating the metal-containing material; and transferring heat from the metal-containing material to the high-k material to locally anneal the high-k material, wherein the temperature within the chamber during the method is below 500° C.

In accordance with yet further exemplary embodiments of the disclosure, a substrate processing apparatus is provided for performing a method as described herein.

### BRIEF DESCRIPTION OF THE DRAWINGS

FIG. 1 illustrates a method in accordance with one or more embodiments of the disclosure.

FIG. 2 is a cross-sectional view of a substrate processing apparatus in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not modify the individual elements of the list.

As used herein, the singular forms “a,” “an,” and “the” are intended to include the plural forms as well, unless the context clearly indicates otherwise. It will be further understood that the terms “includes,” “comprises,” “including,” and/or “comprising” used herein specify the presence of stated features, integers, steps, processes, members, components, and/or groups thereof; such terms do not preclude the presence or addition of one or more other features, integers, steps, processes, members, components, and/or groups thereof.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. A layer or film can be continuous—or not.

As used herein, the term “structure” can refer to a partially or completely fabricated device structure. By way of examples, a structure can be a substrate or include a substrate with one or more layers and/or features formed thereon.

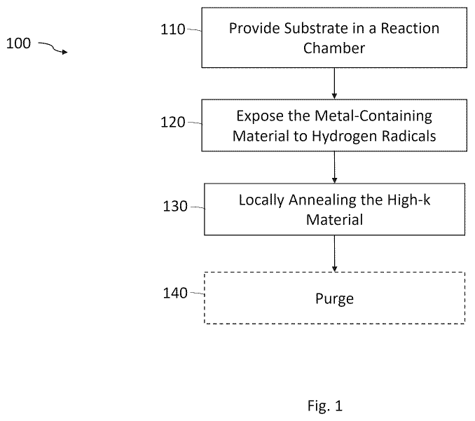

FIG. 1 illustrates a method of annealing in accordance with exemplary embodiments of the disclosure. Method 100 includes providing a substrate in a reaction chamber (step 110), exposing a metal-containing material to hydrogen radicals (step 120), locally annealing a high-k material (step 130), and an optional purge (step 140).

During step 110, a substrate is provided into a reaction chamber. In accordance with examples of the disclosure, the reaction chamber can form part of a chemical vapor deposition reactor, such as a chemical vapor deposition (CVD) reactor, an atomic layer deposition (ALD) reactor, a plasma-enhanced chemical vapor deposition (PECVD) reactor, or a plasma-enhanced atomic layer deposition (PEALD) reactor. Various steps of methods described herein can be performed within a single reaction chamber or can be performed in multiple reaction chambers, such as reaction chambers of a cluster tool. The substrate comprises a metal-containing material on a surface of the substrate, and a high-k material in proximity to or in direct contact with the metal-containing material. In some embodiments, the high-k material is in direct contact with the metal-containing material. In some embodiments, the high-k material is at least partially co-planar with the metal-containing material. In some embodiments, the high-k material is at least partially disposed beneath (e.g., in direct contact with) the metal-containing material.

The metal-containing material comprises metal atoms. In some examples, the metal-containing material is a metal, a metal alloy, or other conductive material, such as metal nitride. As used herein, conductive material has a resistivity of less than about 2000 μΩcm, or less than about 1000 μΩcm, or less than about 500 μΩcm, or less than about 200 μΩcm. The metal containing material can be metallic, e.g., consists of or consists essentially of one or more metal atoms. In some embodiments, the metal-containing material consists essentially of metal. In some embodiments, the metal-containing material is or comprises titanium nitride.

In some embodiments, the high-k material has a dielectric constant greater than about 9, or greater than about 12, or between about 12 and 15. In some embodiments, the high-k material is or comprises a metal oxide, or a complex metal oxide, such as hafnium zirconium oxide. In some embodiments, the high-k material is amorphous during step 110.

During step 110, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than about 500° C., or less than 400° C. or between about 300° C. and 500° C., or between about 350° C. and 400° C. By way of examples, a pressure within a reaction chamber can be less than or equal to 20 torr, or less than or equal to about 10 torr, or less than or equal to about 5 torr or, preferably, in the range of about 1 torr to about 10 torr.

During step 120, the metal-containing material is exposed to hydrogen radicals. The hydrogen radical may come from any suitable source. In some embodiments, the hydrogen radicals are produced in a remote plasma source and/or an indirect plasma source or chamber and are flowed into the reaction chamber and/or a reaction space. The hydrogen radicals may be mixed with an inert or carrier gas, such as one or more of helium, argon, and neon. A duration of step 120 can be greater than about 2 seconds, greater than about 30 seconds, or between about 30 seconds and 300 seconds.

In some embodiments, the temperature in the reaction chamber during the step of exposing the metal-containing materials is less than about 500° C., or less than 400° C. or between about 300° C. and 500° C., or between about 350° C. and 400° C.

In some embodiments, the hydrogen radicals may recombine into diatomic hydrogen (H₂) at or near the metal-containing material. Not to be bound by theory, it is thought that the recombination of the hydrogen radicals produces thermal energy that is absorbed by the metal-containing material, thereby locally heating the metal-containing material.

During step 130, the high-k material is locally annealed. Locally annealing the high-k material may anneal the high-k material within about 150 Angstroms, or within 120 Angstroms of the metal-containing material. The metal-containing material may transfer some of its thermal energy to the high-k material. The step 120 of locally annealing may increase the crystallinity of the high-k material. In some embodiments, the step 120 of locally annealing may change the high-k material from amorphous to crystalline. In some embodiments, a theta x-ray diffraction (XRD) scan of an example high-k material after the step of locally annealing shows discernible peaks. Although illustrated as separate steps, step 120 and step 130 can overlap in time and can happen at about the same time.

In some embodiments, the dielectric constant of the high-k material is greater than 15 after the step of locally annealing the high-k material and/or is increased by more than 3, or more than 6.

During step 140, a purge is performed. During step 140, any remaining hydrogen radicals and diatomic hydrogen may be removed from the reaction chamber. During step 140, a purge gas can be provided to the reaction chamber for a purge period. The purge gas can be or include an inert gas and/or nitrogen. A duration of the purge period can be greater than 2 seconds, or between about 5 seconds and 30 seconds.

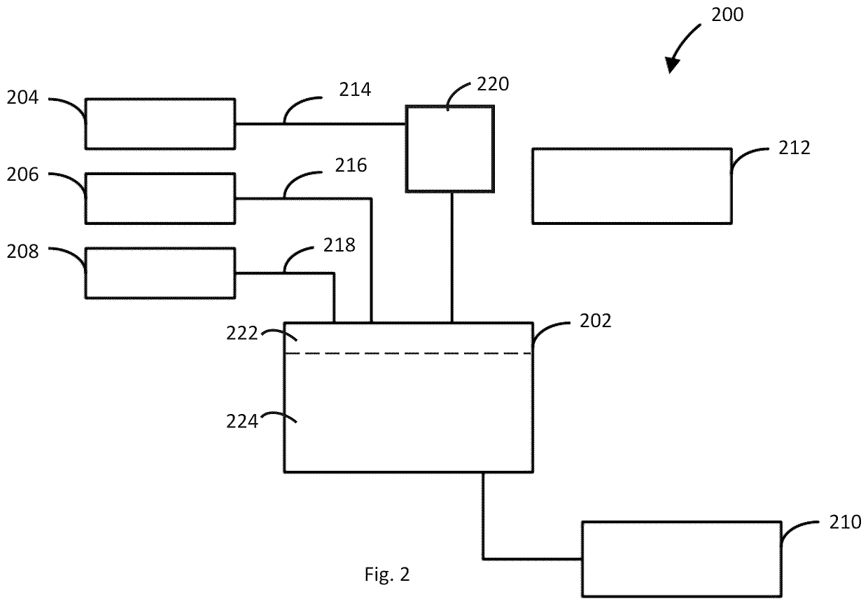

FIG. 2 illustrates an example of a substrate processing apparatus 200 in accordance with one or more examples of the disclosure. Apparatus 200 can be used to perform a method as described herein and/or form a structure or device portion as described herein. For example, apparatus 200 can deposit the high-k material and/or the metal-containing material, as described herein, and/or perform a method of annealing, as described herein.

In the illustrated example, apparatus 200 includes one or more reaction chambers 202, a hydrogen gas source 204, an inert/carrier gas source 206, an additional gas source 208, an exhaust source 210, a controller 212, and a remote plasma source 220.

Reaction chamber 202 can include any suitable reaction chamber, such as an atomic layer deposition (ALD), chemical vapor deposition (CVD) reaction chamber, or the like.

Hydrogen gas source 204 can include a vessel and one or more hydrogen containing gases, such as H₂, as described herein-alone or mixed with one or more carrier (e.g., inert) gases. Inert/carrier gas source 206 can include a vessel and one or more inert or carrier gases. Exemplary inert and/or carrier gases include Ar, He, and N₂. Source 205 can include one or more precursors and/or reactants used to form the high-k material and/or the metal-containing material. Although illustrated with three gas sources 204-208, apparatus 200 can include any suitable number of gas sources. Gas sources 204-208 can be coupled to reaction chamber 202 via lines 214-218, which can each include flow controllers, valves, heaters, and the like. Hydrogen gas source 204 is coupled to remote plasma source 220 configured to produce hydrogen radicals. Additionally or alternatively, hydrogen radicals can be formed using an indirect plasma chamber 222. The hydrogen radicals produced in indirect plasma chamber 222 can flow to a reaction space 224.

Exhaust source 210 can include one or more vacuum pumps. For example, exhaust source 210 can include one or more of a turbomolecular pump and/or a cryopump.

Controller 212 includes electronic circuitry and software to selectively operate valves, manifolds, heaters, pumps, and other components included in the apparatus 200. Such circuitry and components operate to introduce precursors, reactants, and gases from the respective sources 204-208. Controller 212 can control timing of gas pulse sequences, temperature of the substrate and/or reaction chamber, pressure within the reaction chamber, and various other operations to provide proper operation of the apparatus 200. Controller 212 can include control software to electrically or pneumatically control valves to control flow of precursors, reactants, and purge gases into and out of the reaction chamber 202. Controller 212 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 200 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 202. Further, as a schematic representation of a system, many components have been omitted for simplicity of illustration, and such components may include, for example, various valves, manifolds, purifiers, heaters, containers, vents, and/or bypasses.

During operation of apparatus 200, substrates, such as semiconductor wafers (not illustrated), are transferred from, e.g., a substrate handling system to reaction chamber 202. Once substrate(s) are transferred to reaction chamber 302, one or more gases from gas sources 204-208, such as precursors, reactants, carrier gases, and/or purge gases, are introduced into reaction chamber 202.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for annealing, the method comprising:
providing a substrate in a chamber, wherein the substrate comprises a metal-containing material on a surface of the substrate and a high-k material in proximity to or in contact with the metal-containing material;
exposing the metal-containing material to hydrogen radicals, wherein the hydrogen radicals recombine at or near the metal-containing material thereby locally heating the metal-containing material; and
locally annealing the high-k material,
wherein the temperature within the chamber during the method is less than 500° C.

2. The method of claim 1, wherein locally annealing the high-k material comprises heat transfer from the metal-containing material to the high-k material.

3. The method of claim 1, wherein the metal-containing material is metallic.

4. The method of claim 1, wherein the metal-containing material consists essentially of a metal.

5. The method of claim 1, wherein the metal-containing material comprises a metal nitride.

6. The method of claim 5, wherein the metal nitride comprises titanium nitride.

7. The method of claim 1, wherein locally annealing the high-k material increases the crystallinity of the high-k material.

8. The method of claim 1, wherein the dielectric constant of the high-k material is greater than 12 before locally annealing.

9. The method of claim 1, wherein the dielectric constant of the high-k material is greater than 15 after locally annealing.

10. The method of claim 1, wherein the metal-containing material is a metal interconnect disposed in a gap on the surface of the substrate.

11. The method of claim 1, where recombining the hydrogen radicals produces H₂, and wherein the method further comprises a purge of the H₂.

12. The method of claim 1, wherein the high-k material comprises a metal oxide.

13. The method of claim 1, wherein the high-k material is annealed up to a thickness within 150 Angstroms of the metal-containing material.

14. The method of claim 1, wherein the step of exposing the metal-containing material to the hydrogen radicals comprises flowing the hydrogen radicals from a remote plasma source.

15. The method of claim 1, wherein the step of exposing the metal-containing material to the hydrogen radicals consists of flowing the hydrogen radicals and a carrier gas.

16. The method of claim 1, wherein the metal-containing material is in contact with the high-k material.

17. The method of claim 16, wherein the metal-containing material is co-planar with the high-k material.

18. The method of claim 16, wherein the metal-containing material is disposed above the high-k material.

19. The method of claim 1, wherein the temperature during the method is below 400° C.

20. A method for annealing, the method comprising:
providing a substrate in a chamber, wherein the substrate comprises a metal-containing material on a surface of the substrate and a high-k material in contact with the metal-containing material, wherein the high-k material comprises a metal oxide and the metal-containing material comprises titanium nitride;
exposing the metal-containing material to hydrogen radicals, wherein the hydrogen radicals recombine at or near the metal-containing material thereby locally heating the metal-containing material; and
transferring heat from the metal-containing material to the high-k material to locally anneal the high-k material,
wherein the temperature within the chamber during the method is below 500° C.
